(19) United States
(12) Patent Application Publication
(10) Pub. No.: US 2026/0231785 A1
(43) Pub. Date: Aug. 6, 2026

(54) INSULATION STRUCTURE FOR ELECTRICAL ISOLATION

(71) Applicant: TEXAS INSTRUMENTS INCORPORATED, DALLAS, TX (US)

(72) Inventors: RONGWEI ZHANG, PLANO, TX (US); ENIS TUNCER, DALLAS, TX (US); HANK SUNG, SACHSE, TX (US)

(21) Appl. No.: 19/043,129

(22) Filed: Jan. 31, 2025

(51) Int. Cl. H01L 23/495; H01L 21/48; H01L 21/56; H01L 23/00

(52) U.S. Cl. CPC H10W 70/435; H10W 70/042; H10W 70/457; H10W 70/458; H10W 74/016; H10W 72/0198; H10W 72/073; H10W 72/075; H10W 72/931; H10W 74/00; H10W 90/736; H10W 90/756

(57) ABSTRACT

A semiconductor device includes a conductive layer including a first lead and a second lead separated by a gap. The conductive layer extends from a first conductive surface to a second conductive surface in a first direction and from a first lead outer edge of the first lead to a second lead outer edge of the second lead in a second direction. The semiconductor device also includes an insulation structure applied to the first conductive surface of the conductive layer and extending continuously from the first lead outer edge to the second lead outer edge. The insulation structure includes an adhesive layer and an insulation layer separated from the conductive layer by the adhesive layer. The semiconductor further includes a die affixed to the adhesive layer in the gap. The semiconductor device yet further includes bond wires between the die and the first lead and the second lead.

### TECHNICAL FIELD

This description relates to affixing a die, of a semiconductor device, to an insulation structure to mitigate electrical leakage.

### BACKGROUND

The semiconductor industry has utilized various methods and equipment to singulate individual semiconductor die from a semiconductor wafer. For example, a technique called scribing or dicing is used to either partially or fully cut through the semiconductor wafer with a diamond cutting wheel or a wafer saw along scribe lines formed on the semiconductor wafer between the individual die. During mechanical dicing, the semiconductor wafer may splinter embedding chips in the isolation layers resulting in electrical leakage between the layers of the semiconductor device. Laser dicing suffers from similar flaws as mechanical dicing. Laser dicing melts or sublimates a portion of the semiconductor wafer inside the material interaction zone, which can have a deleterious effect on the crystalline structure of the semiconductor wafer further splintering embedding chips in the isolation layers resulting in electrical leakage between the layers of the device.

### SUMMARY

In a first example, a semiconductor device is provided. The semiconductor device includes a conductive layer including a first lead and a second lead separated by a gap. The conductive layer extends from a first conductive surface to a second conductive surface in a first direction and from a first lead outer edge of the first lead to a second lead outer edge of the second lead in a second direction. The semiconductor device also includes an insulation structure applied to the first conductive surface of the conductive layer and extending continuously from the first lead outer edge to the second lead outer edge. The insulation structure includes an adhesive layer and an insulation layer separated from the conductive layer by the adhesive layer. The semiconductor device further includes a die affixed to the adhesive layer in the gap. The semiconductor device yet further includes bond wires between the die and the first lead and the second lead.

In a second example, an integrated circuit (IC) device is provided. The IC device includes a conductive layer including a first lead and a second lead separated by a gap. The conductive layer extends from a first conductive surface to a second conductive surface in a first direction and from a first lead outer edge of the first lead to a second lead outer edge of the second lead in a second direction. The IC device also includes an insulation structure applied to the first conductive surface of the conductive layer and extending continuously from the first lead outer edge to the second lead outer edge. The insulation structure includes an adhesive layer and an insulation layer separated from the conductive layer by the adhesive layer. The IC device further includes a die affixed to the adhesive layer in the gap. The IC device yet further includes bond wires between the die and the first lead and the second lead. The IC device includes a mold compound including a first mold section encapsulating the bond wires, the first lead, the second lead, the die, and the insulation structure, and a second mold section formed on the insulation layer of the insulation structure. The IC device also includes a substrate having a first terminal and a second terminal. The IC device further includes a solder layer having a first solder portion over the first terminal and a second solder portion over the second terminal. The first lead is affixed to the first terminal at the first solder portion and the second lead is affixed to the second terminal at the second solder portion.

In a third example, a method for forming a semiconductor device is provided. The method includes providing a conductive layer having a first conductive surface and a second conductive surface. The method also includes applying an insulation structure to the first conductive surface of the conductive layer. The insulation structure includes an adhesive layer and an insulation layer separated from the conductive layer by the adhesive layer. The method further includes patterning the conductive layer to form a first lead and a second lead separated by a gap exposing the adhesive layer. The method yet further includes affixing a die to the adhesive layer in the gap. The method includes attaching bond wires between the die and the first lead and the second lead. The method also includes encapsulating the bond wires, the first lead, the second lead, the die, and the insulation structure in a mold compound to form a semiconductor device.

### BRIEF DESCRIPTION OF THE DRAWINGS

FIG. 1 illustrates a cross-sectional view of an example of a semiconductor device having an insulation structure.

FIG. 2 illustrates a cross-sectional view of an example of an integrated circuit (IC) device having an insulation structure and affixed to a substrate.

FIG. 3 illustrates a cross-sectional view of an example of an IC device having an insulation structure and affixed over a substrate with bond pillars.

FIG. 4 illustrates a cross-sectional view of an example of an IC device having an insulation structure and affixed into a recess of a substrate.

FIGS. 5-15 illustrate example stages of a method of forming a semiconductor device having an insulation structure.

FIG. 16 illustrates a flowchart of an example method for fabricating a semiconductor device having an insulation structure.

### DETAILED DESCRIPTION

Electronic leakage caused by silicon chipping and debris is a leading cause of failure for integrated circuit (IC) devices. Conventional methods use a two-stage curing process to isolate the layers of the IC device including coating a wafer with a first stage layer to capture debris followed by a second stage layer to adhere the dies to a leadframe. Here, a die is affixed to an insulation structure relative to leads, patterned from a conductive layer, for wire bonding. The insulation structure isolates splinters and chipping that result from dicing (e.g., mechanical dicing, laser dicing, etc.) of the die from the leads without a two-stage curing process, thereby simplifying the manufacturing process. Furthermore, because the die is affixed to the insulation structure, a leadframe having a die pad is not required, which reduces material costs.

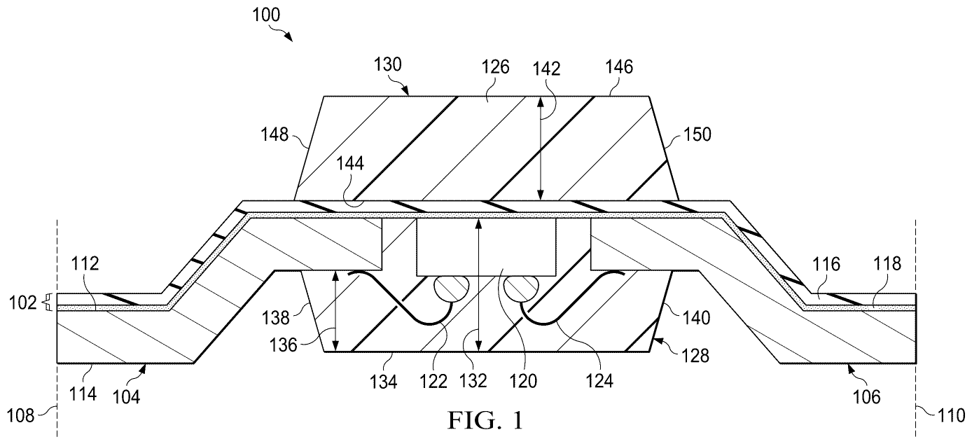

FIG. 1 illustrates a cross-sectional view of an example of a semiconductor device 100 having an insulation structure 102 over a first lead 104, and a second lead 106 in a first direction. The insulation structure 102 extends continuously from a first lead outer edge 108 to a second lead outer edge 110 in a second direction approximately orthogonal to the first direction. The first lead 104 and the second lead 106 are separated by a gap and are thus discontinuous in the second direction. The first lead 104 and the second lead 106 are formed of a conductive layer of an electrically conductive material, such as copper, palladium, gold, silver, or other appropriate conductive metal or metal alloys with similar properties. The first lead 104 and the second lead 106 have a first conductive surface 112 in contact with the insulation structure 102 opposite a second conductive surface 114.

The insulation structure 102 is formed of an insulation layer 116 formed over an adhesive layer 118. The insulation layer 116 is formed of an insulation material that is nonconductive, and is, for example, polyphenylene sulfide (PPS), polyetherimide (PEI), polyimide, polyamide-imide (PAI), polysulfone, polytetrafluoroethylene (PTFE), vespel, liquid crystal polymer or other suitable material with similar properties. The adhesive layer 118 provides adhesion between the first conductive surface 112 of the first lead 104 and the second lead 106 and the insulation layer 116. The gap between the first lead 104 and the second lead 106 exposes a portion of the adhesive layer 118. The adhesive layer 118 is formed of an insulation material such as a thermoset resin including phenolic resins, benzoxazines, phthalonitriles or other suitable material with similar properties.

A die 120 is affixed to the adhesive layer 118 in the gap. The die 120 is connected to the first lead 104 with a first bond wire 122 and the second lead 106 with a second bond wire 124. The first bond wire 122 and the second bond wire 124 are formed of a conductive material such as copper (Cu). At least a portion of the semiconductor device 100 is incapsulated in a mold compound 126. In some examples, the mold compound 126 is formed of one or more insulating materials, such as organic resins (e.g., epoxy), inorganic resins, and/or other suitable materials. The mold compound 126 includes a first mold section 128 and/or a second mold section 130. The first mold section 128 encapsulates a portion of the first lead 104, the second lead 106, the die 120, the first bond wire 122, and the second bond wire 124. The second mold section is formed over the insulation structure 102.

The first mold section 128 has a first mold section height 132 extending from the insulation structure 102 to mold section outer surface 134 in the first direction. The first mold section 128 has a first mold section dimension 136 extending from the second conductive surface 114 to a mold section outer surface 134 in the first direction. The first mold section height 132 is greater than the first mold section dimension 136. Furthermore, the second conductive surface 114 extends further from the die 120 in the first direction than the mold section outer surface 134. The first mold section 128 also includes a first molding sidewall 138 opposite a second molding sidewall 140 in the second direction. The first molding sidewall 138 extends from the first lead 104 toward the mold section outer surface 134. The second molding sidewall 140 extends from the second lead 106 toward the mold section outer surface 134. In some examples, the molding sidewalls 138, 140 extend continuously at angle relative to the mold section outer surface 134 such that the molding sidewalls 138, 140 are tapered.

The second mold section 130 has a second mold section height 142 extending from a lower surface 144 at the insulation layer 116 to an upper surface 146 in the first direction. The second mold section 130 has a third molding sidewall 148 opposite a fourth molding sidewall 150 in the second direction. In some examples, the first molding sidewall 138 and the third molding sidewall 148 are approximately colinear and the second molding sidewall 140 and the fourth molding sidewall 150 are approximately colinear. The molding sidewalls 148, 150 extend continuously at an angle from the lower surface 144 to the upper surface 146. The angle is relative to lower surface 144 and may be less than ninety degrees.

The insulation structure 102 and the first lead 104 extend beyond the first molding sidewall 138 and the third molding sidewall 148 to the first lead outer edge 108. Similarly, the insulation structure 102 and the second lead 106 extend beyond the second molding sidewall 140 and the fourth molding sidewall 150 to the second lead outer edge 110. The insulation structure 102 extends continuously through the mold compound 126. The first lead 104 and the second lead 106 are formed on the adhesive layer 118 of the insulation structure 102. The insulation structure 102 provides support for the die 120 so that a die pad in unnecessary, thereby reducing material usage.

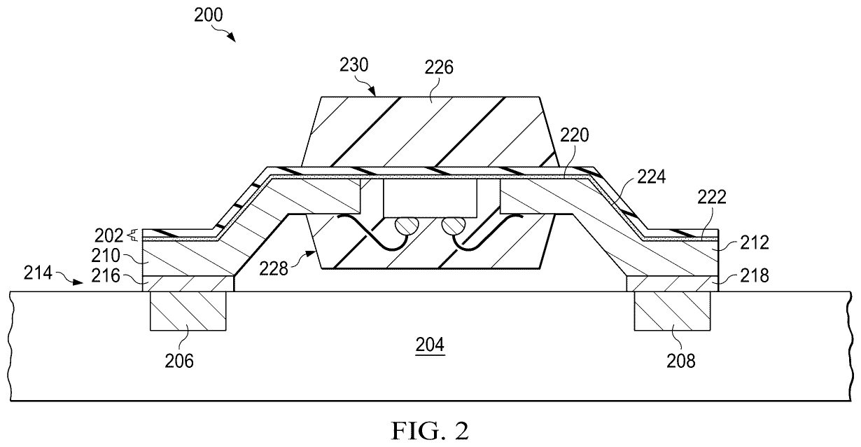

FIG. 2 illustrates a cross-sectional view of an example of an IC device having a semiconductor device 200 (e.g., the semiconductor device 100 of FIG. 1) including an insulation structure 202 (e.g., the insulation structure 102 of FIG. 1) and a substrate 204. The substrate 204 is silicon, silicon carbide, organic material, or other suitable material, either in substantially pure form or in combination with additional materials. As one example, the substrate 204 is a single crystal material, such as a single crystal silicon substrate. As another example, the substrate 204 is a complementary metal-oxide semiconductor (CMOS) substrate. As yet another example, the substrate 204 is a printed circuit board (PCB). The formation of the substrate 204 is dependent on the application of the resulting IC device. In some examples, the substrate 204 includes components such as one or more passive elements (e.g., resistors, capacitors, transistors, inductors, etc.) and/or one or more sources (e.g., voltage and/or current sources, etc.).

The substrate 204 also includes a first terminal 206 and a second terminal 208 that provide an electrical connection to a first lead 210 (e.g., the first lead 104 of FIG. 1) and a second lead 212 (e.g., the second lead 106 of FIG. 1) respectively. The first terminal 206 and the second terminal 208 are formed of a conductive material. The leads 210, 212 are affixed to the terminals 206, 208 by a solder layer 214. The solder layer 214 includes a first solder portion 216 at the first terminal 206 and a second solder portion 218 at the second terminal 208. Accordingly, the first lead 210 is affixed to the first terminal 206 at the first solder portion 216 and the second lead 212 is affixed to the second terminal 208 at the second solder portion 218. The solder layer 214 is formed of a solderable metal material. In some examples, the solderable metal material include various forms of nickel, palladium, tin, gold, etc. While two terminals corresponding to two leads are described, more or fewer terminals and leads may be utilized to affix the semiconductor device 200 to the substrate 204 with the solder layer 214.

A surface of the first lead 210 and the second lead 212 is affixed to the insulation structure 202. For example, the insulation structure 202 is affixed continuously over the first lead 210 and the second lead 212 and spans the gap between the first lead and the second lead 212 in the first direction. In some examples, the first lead 210 and the second lead 212 are shaped to accommodate the semiconductor device 200 being affixed to the substrate 204 with the solder layer 214. For example, the first lead 210 includes a first lead portion 220 and a second lead portion 222 extending in the second direction. The first lead portion 220 and the second lead portion 222 are separated by a third lead portion 224 extending in approximately the first direction. The third lead portion 224 may be angled relative to the substrate 204. The third lead portion 224 provides the semiconductor device 200 a height that lifts the mold compound 226 (e.g., the mold compound 126 of FIG. 1) over the substrate 204. The first mold section 228 (e.g., first mold section 128 of FIG. 1) is separated from the substrate 204 by a separation distance 230.

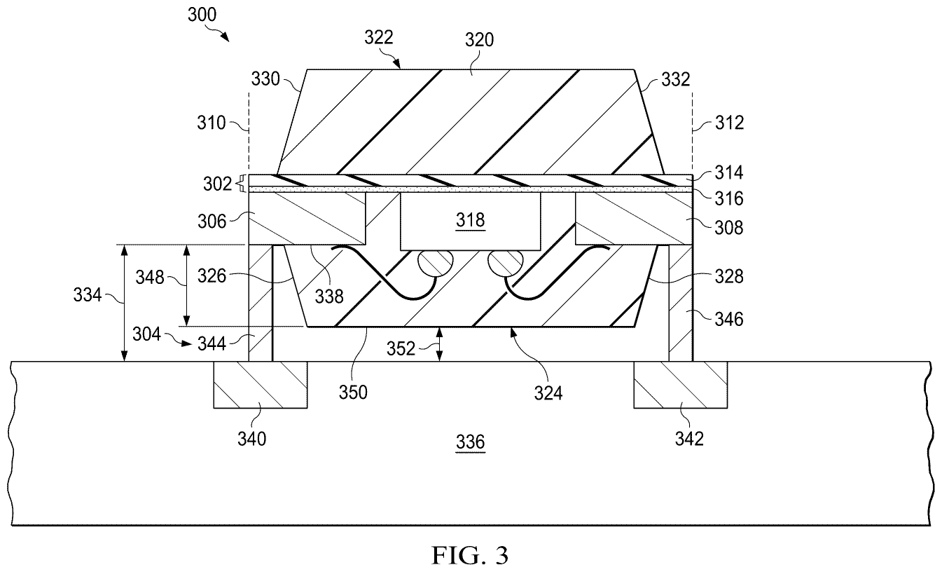

FIG. 3 illustrates a cross-sectional view of an example of an IC device including a semiconductor device 300 (e.g., the semiconductor device 100 of FIG. 1, the semiconductor device 200 of FIG. 2) having an insulation structure 302 (e.g., the insulation structure 102 of FIG. 1, the insulation structure 202 of FIG. 2). In addition to the shape of the leads 306, 308 contributing to the position of the semiconductor device 300, a solder layer 304 (e.g., the solder layer 214 of FIG. 2) may additionally or alternatively contribute to the position of the semiconductor device 300.

A first lead 306 (e.g., the first lead 104 of FIG. 1, the first lead 210 of FIG. 2) and a second lead 308 (e.g., the second lead 106 of FIG. 1, the second lead 212 of FIG. 2) are separated by a gap in a first direction. The insulation structure 302 extends over the first lead 306 and the second lead 308 in a first direction. The insulation structure 302 extends continuously over the first lead 306 and the second lead 308 from a first lead outer edge 310 (e.g., the first lead outer edge 108 of FIG. 1) to a second lead outer edge 312 (e.g., the second lead outer edge 110 of FIG. 1) in a second direction approximately orthogonal to the first direction. The first lead 306 and the second lead 308 are separated by a gap in the second direction.

The insulation structure 302 is formed of an insulation layer 314 (e.g., the insulation layer 116 of FIG. 1) formed over an adhesive layer 316 (e.g., the adhesive layer 118 of FIG. 1). A die 318 (e.g., the die 120 of FIG. 1) is affixed to the adhesive layer 316 in the gap. At least a portion of the semiconductor device 300 is incapsulated in a mold compound 320 (e.g., the mold compound 126 of FIG. 1). The mold compound 320 includes a first mold section 322 (e.g., the first mold section 128 of FIG. 1, the first mold section 228 of FIG. 2) and a second mold section 324 (e.g., the second mold section 130 of FIG. 1). The first mold section 322 encapsulates a portion of the first lead 306, the second lead 308, and the die 318. The first mold section 322 includes a first molding sidewall 326 opposite a second molding sidewall 328 in the second direction. The second mold section 324 has a third molding sidewall 330 opposite a fourth molding sidewall 332 in the second direction.

In some examples, the first lead outer edge 310 is approximately collinear with the first molding sidewall 326 of the first mold section 322 and/or the third molding sidewall 330 of the second mold section 324. Likewise, the second lead outer edge 312 is approximately collinear with the second molding sidewall 328 of the first mold section 322 and/or the fourth molding sidewall 332 of the second mold section 324. In other examples, a portion of the leads 306, 308 extends beyond the sidewalls of the mold compound 320. For example, the first lead 306 extends beyond the first molding sidewall 326 of the first mold section 322 and/or the third molding sidewall 330. The second lead 308 the second molding sidewall 328 of the first mold section 322 and/or the fourth molding sidewall 332 of the second mold section 324.

The solder layer 304 has a solder height 334 from a substrate 336 (e.g., the substrate 204 of FIG. 2) to a conductive surface 338 (e.g., the second conductive surface 114 of FIG. 1) of the leads 306, 308. The substrate 336 includes a first terminal 340 (e.g., the first terminal 206 of FIG. 2) and a second terminal 342 (e.g., the second terminal 208 of FIG. 2), which are formed of a conductive material. The solder layer 304 includes a first solder portion 344 (e.g., the first solder portion 216 of FIG. 2) that extends from the first terminal 340 to the first lead 306 defining the solder height 334. A second solder portion 346 (e.g., the second solder portion 218 of FIG. 2) extends from the second terminal 342 to the second lead 308 defining the solder height 334 in the first direction. The solder height 334 is greater than a mold section dimension 348. The mold section dimension 348 extends from the conductive surface 338 to a mold section outer surface 350 in the first direction. The first mold section 322 is separated from the substrate 336 by a separation distance 352. Accordingly, the first mold section 322 is spaced apart from the substrate 336 by a separation distance 352 based on the solder height 334.

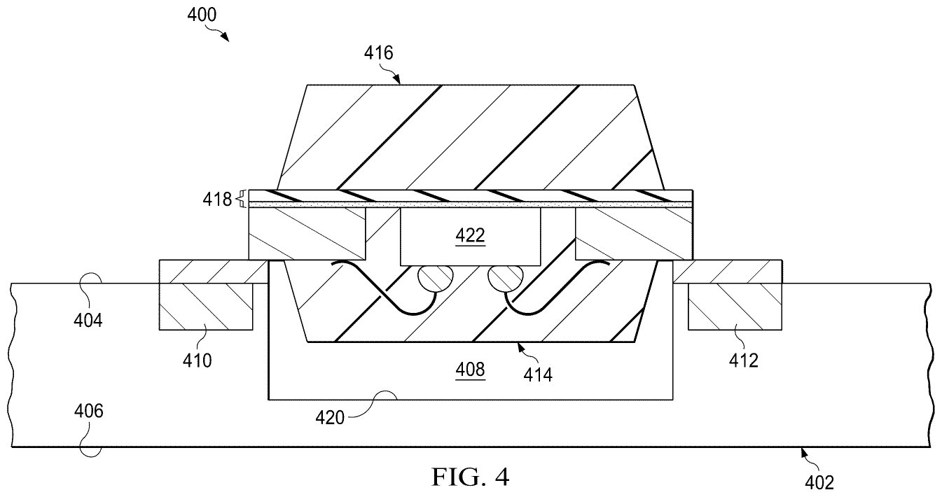

FIG. 4 illustrates a cross-sectional view of an example of an IC device having semiconductor device 400 (e.g., the semiconductor device 100 of FIG. 1, the semiconductor device 200 of FIG. 2, the semiconductor device 300 of FIG. 3) and a substrate 402 (e.g., the substrate 204 of FIG. 2, the substrate 336 of FIG. 3). The substrate 402 has an upper surface 404, a base surface 406, and a recess 408 extending from the upper surface 404 toward the base surface 406. The recess 408 is positioned between a first terminal 410 (e.g., the first terminal 206 of FIG. 2, the first terminal 340 of FIG. 3) and a second terminal 412 (e.g., the second terminal 208 of FIG. 2, the second terminal 342 of FIG. 3) in the upper surface 404.

The semiconductor device 400 includes a first mold section 414 (e.g., the first mold section 128 of FIG. 1, the first mold section 228 of FIG. 2, the first mold section 322 of FIG. 3) separated from a second mold section 416 (e.g., the second mold section 130 of FIG. 1, the second mold section 324 of FIG. 3) by the insulation structure 418 that extends continuously through the semiconductor device 400. The first mold section 414 extends into the recess 408. A lower surface 420 of the recess 408 is spaced apart from the first mold section 414.

The insulation structure 418 (e.g., the insulation structure 102 of FIG. 1, the insulation structure 202 of FIG. 2, the insulation structure 302 of FIG. 3) provides support for a die 422 (e.g., the die 120 of FIG. 1, the die 318 of FIG. 3) in a number of configurations (e.g., FIG. 2, FIG. 3, FIG. 4) without a die pad of a leadframe, which reduces materials costs. Additionally, the insulation structure 418 electrically isolates the die 422 without a two-stage curing process, thereby simplifying the manufacturing process.

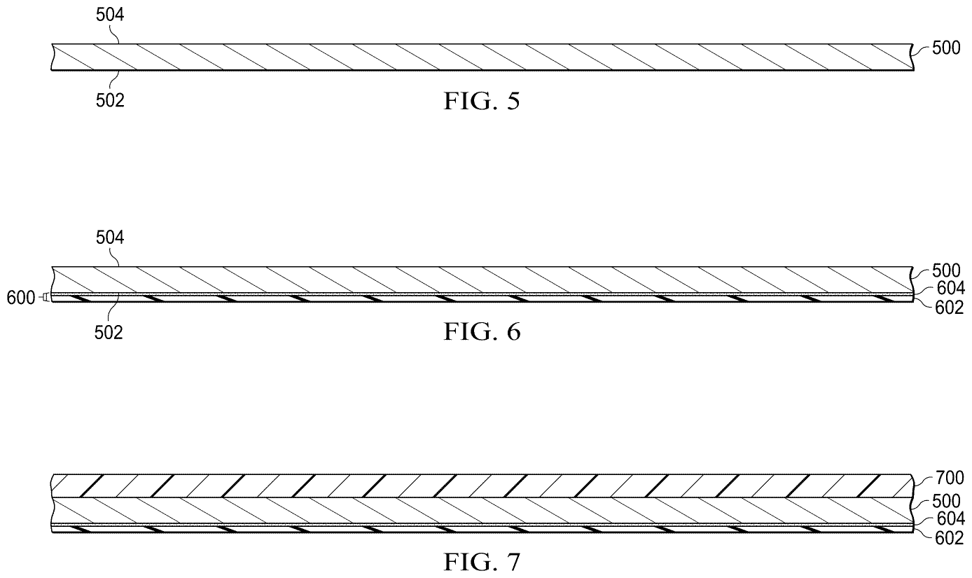

FIGS. 5-16 illustrate example stages of a method of forming a semiconductor device having an insulation structure. For purposes of clarity, FIG. 5-16 employ the same reference numbers to denote the same structure.

FIG. 5 illustrates an example of a first stage of a method of forming a semiconductor device. In the first stage, a conductive layer 500 is provided. The conductive layer 500 is formed of an electrically conductive material, such as copper, palladium, gold, silver, or other appropriate conductive metal or metal alloys with similar properties. In some examples, the conductive layer 500 is a copper foil. The conductive layer 500 has a thickness of approximately 150 microns. The conductive layer 500 has a first conductive surface 502 opposite a second conductive surface 504 in a first direction.

FIG. 6 illustrates an example of a second stage of the method of forming a semiconductor device. In the second stage, the conductive layer 500 is affixed to an insulation structure 600 (e.g., the insulation structure 102 of FIG. 1, the insulation structure 202 of FIG. 2, the insulation structure 302 of FIG. 3, the insulation structure 418 of FIG. 4). The insulation structure 600 includes an insulation layer 602 (e.g., the insulation layer 116 of FIG. 1, the insulation layer 314 of FIG. 3) formed over an adhesive layer 604 (e.g., the adhesive layer 118 of FIG. 1, the adhesive layer 316 of FIG. 3). The insulation structure has a height in the first direction of approximately 5-200 microns. With a height below 5 microns, the insulation structure 600 exhibits poor adhesion and is too flexible to provide support for a die. A height above 200 microns causes the insulation structure 600 to be too stiff.

The insulation layer 602 is formed of an insulator material, such as a polymer matrix material, prepeg material, silicon dioxide (SiO₂), silicon nitride (Si₃N₄), polyimide, benzocyclobutene (BCB), or other suitable materials. The adhesive layer 604 may be a polymer film, thermosetting resins, adhesive agent, etc. In some examples, the insulation structure 600 is a polyimide tape including the insulation layer 602 and the adhesive layer 604. The first conductive surface 502 of the conductive layer 500 is affixed to the adhesive layer 604 of the insulation structure 600.

FIG. 7 illustrates an example of a third stage of the method of forming a semiconductor device. In the third stage, a photoresist layer 700 is formed on the second conductive surface 504. The photoresist layer 700 is a light-sensitive material used in several processes, including photolithography, photoengraving, and photoresist etching that allow underlying layers to be patterned.

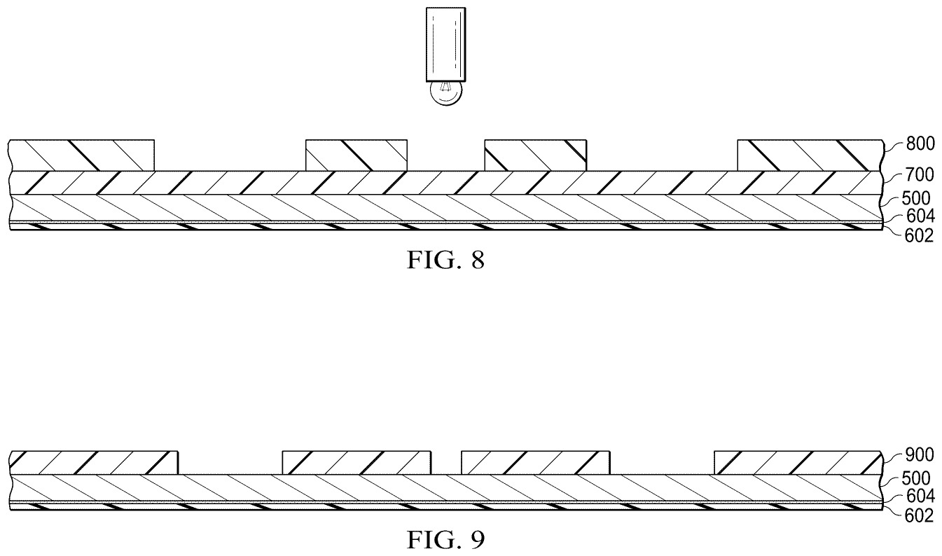

FIG. 8 illustrates an example of a fourth stage of the method of forming a semiconductor device. In the fourth stage, a photomask 800 is applied to the photoresist layer 700. The photomask 800 has a pattern corresponding to the desired etching to form the leads. The photomask 800 is irradiated to pattern the photoresist layer 700.

FIG. 9 illustrates an example of a fifth stage of the method of forming a semiconductor device. In the fifth stage, non-irradiated portions of the photoresist layer 700 are removed forming a patterned photoresist 900. The remaining photomask 800 is then removed.

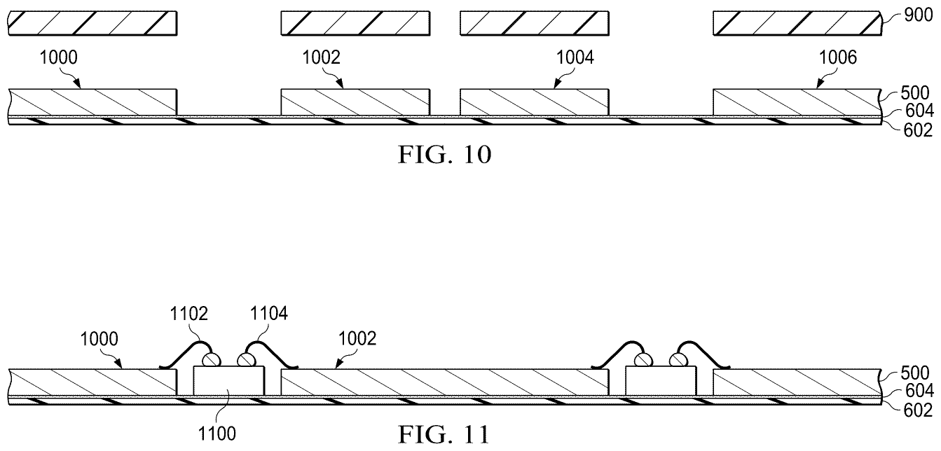

FIG. 10 illustrates an example of a sixth stage of the method of forming a semiconductor device. In the sixth stage, the conductive layer 500 is patterned. For example, a dry plasma etch is performed to remove the conductive material of the conductive layer 500 from the corresponding the removed irradiated portions of the photoresist layer 700. A first lead 1000 (e.g., the first lead 104 of FIG. 1, the first lead 210 of FIG. 2, the first lead 306 of FIG. 3), a second lead 1002 (e.g., the second lead 106 of FIG. 1, the second lead 212 of FIG. 2, the second lead 308 of FIG. 3), a third lead 1004, and a fourth lead 1006 are formed by the etching. The patterned photoresist 900 is then removed.

FIG. 11 illustrates an example of a seventh stage of the method. For clarity, the remaining stages will be shown and described with respect to a single die and a portion of the insulation structure 600 although the dies may be in strip form or provided on a carrier.

In the seventh stage, a die 1100 (e.g., the die 120 of FIG. 1, the die 318 of FIG. 3, the die 422 of FIG. 4) is mounted to the adhesive layer 604 of the insulation structure 600. A first bond wire 1102 (e.g., the first bond wire 122 of FIG. 1) and a second bond wire 1104 (e.g., the second bond wire 124) are attached at the die 1100 and at the first lead 1000 and a second lead 1002. The bond wires 1102, 1104 form an electrical connection between the die 1100 and the leads 1000, 1002.

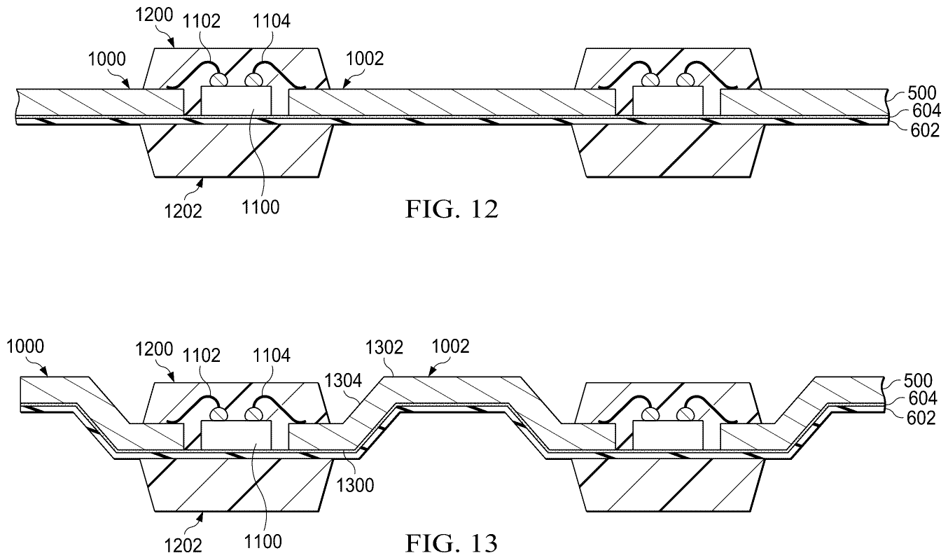

FIG. 12 illustrates an example of an eighth stage of the method. In the eighth stage, at least a portion of the conductive layer 500 and/or the insulation structure 600 is incapsulated in a mold compound (e.g., the mold compound 126 of FIG. 1, the mold compound 226 of FIG. 2) to form a first mold section 1200 (e.g., the first mold section 128 of FIG. 1, the first mold section 228 of FIG. 2, the first mold section 322 of FIG. 3, the first mold section 414 of FIG. 4). In some examples, the mold compound 126 is formed of one or more insulating materials, such as organic resins (e.g., epoxy), inorganic fillers, and/or other suitable materials.

In some examples, at least another portion of the semiconductor device is incapsulated in a mold compound (e.g., the mold compound 126 of FIG. 1, the mold compound 226 of FIG. 2) at the insulation layer 602 of the insulation structure 600. Applying the mold compound to the insulation layer forms a second mold section 1202 (e.g., the second mold section 130 of FIG. 1, the second mold section 324 of FIG. 3).

FIG. 13 illustrates an example of a ninth stage of the method. In the ninth stage, the conductive layer 500, forming the leads 1000, 1002, and the insulation structure 600 may be shaped based on the configuration of the IC device. In one example, the conductive layer 500 is shaped such that the first lead 1000 includes a first lead portion 1300 (e.g., the first lead portion 220 of FIG. 2) and a second lead portion 1302 (e.g., the second lead portion 222 of FIG. 2) extending in the second direction. The first lead portion 1300 and the second lead portion 1302 are separated by a third lead portion 1304 (e.g., the third lead portion 224) extending in approximately the first direction, as shown in FIGS. 1 and 2. The first lead portion 1300, the second lead portion 1302, and/or the third lead portion 1304 may be angled in the first direction and/or the second direction to position the leads 1000, 1002 based on the configuration of a resulting IC device.

In some examples, the conductive layer 500 and/or the insulation structure 600 are shaped so that the second conductive surface 504 extends further in the first direction than a mold section outer surface (e.g., the mold section outer surface 134 of FIG. 1) of the first mold section 1200.

In another example, shaping the semiconductor device includes trimming the conductive layer 500 and the insulation structure 600 to form a first lead outer edge (e.g., a first lead outer edge 310 of FIG. 3) parallel to a first sidewall (e.g., first molding sidewall 326 of FIG. 3) and a second lead outer edge (e.g., second lead outer edge 312 of FIG. 3) parallel to the second sidewall (e.g., the second molding sidewall 328 of FIG. 3), as shown in FIG. 3. In yet another example, the conductive layer 500 is trimmed to provide a chip on lead configuration for to be positioned in a recess (e.g., the recess 408 of FIG. 4) of a substrate, as shown in FIG. 4. The trimming may be performed before or after shaping the leads 1000, 1002, and the insulation structure 600.

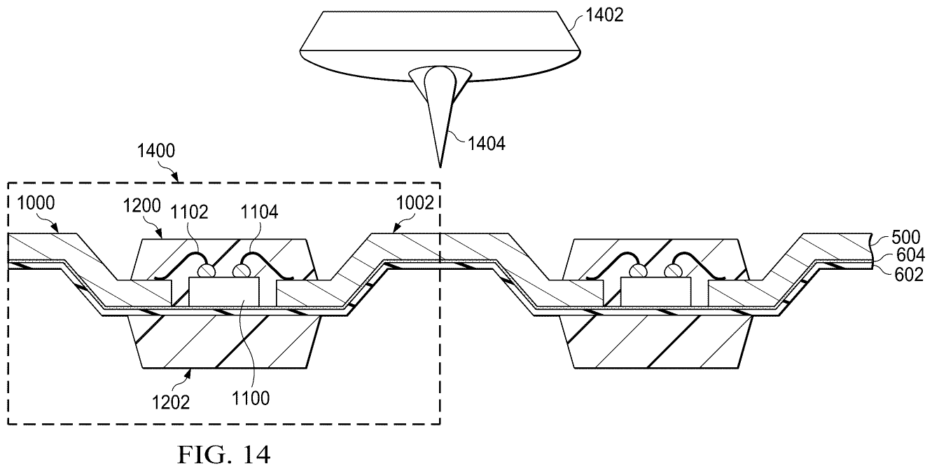

FIG. 14 illustrates an example of a tenth stage of the method of forming a semiconductor device. In the tenth stage, the insulation structure 600 is singulated resulting in a semiconductor device 1400 (e.g., the semiconductor device 100 of FIG. 1, the semiconductor device 200 of FIG. 2, the semiconductor device 300 of FIG. 3, the semiconductor device 400 of FIG. 4). The singulation process utilizes a severing tool 1402. For example, the severing tool 1402 is a saw that includes a saw blade 1404 that scribes, saws or dices through the conductive layer 500 and/or the insulation structure 600 in the first direction. In another example, the severing tool 1402 may be a punching machine that punches semiconductor devices 1400 from a frame.

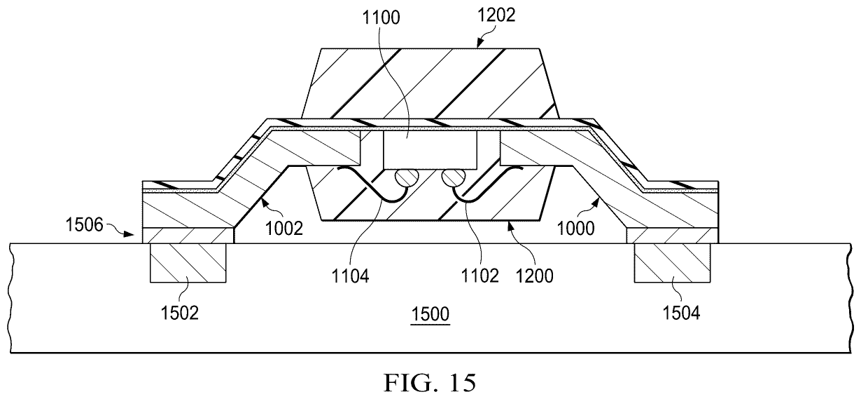

FIG. 15 illustrates an example of a eleventh stage of the method. In the eleventh stage, a substrate 1500 (e.g., the substrate 204 of FIG. 2, the substrate 336 of FIG. 3, the substrate 402 of FIG. 4) is provided. The substrate 1500 also includes a first terminal 1502 (e.g., the first terminal 206 of FIG. 2, the first terminal 340 of FIG. 3, the first terminal 410 of FIG. 4) and a second terminal 1504 (e.g., the second terminal 208 of FIG. 2, the second terminal 342 of FIG. 3, the second terminal 412 of FIG. 4) that provide an electrical connection to a first lead 1000 and a second lead 1002. The first lead 1000 and the second lead 1002 are affixed to the first terminal 1502 and the second terminal 1504 by a solder layer 1506.

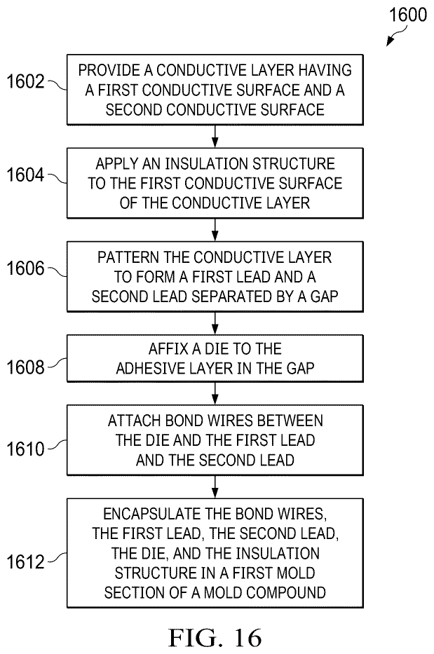

FIG. 16 illustrates a flowchart of an example method for fabricating a semiconductor device having an insulation structure. FIG. 16 will also be described with reference to FIGS. 1-15. For simplicity, the method 1600 will be described as a sequence of blocks, but it is understood that the elements of the method 1600 can be organized into different architectures, elements, stages, and/or processes.

At block 1602, the method 1600 includes providing a conductive layer (e.g., the conductive layer 500 of FIG. 5) having a first conductive surface (e.g., the first conductive surface 112 of FIG. 1, the first conductive surface 502 of FIG. 5) and a second conductive surface (e.g., the second conductive surface 114 of FIG. 1, the second conductive surface 504 of FIG. 5).

At block 1604, the method 1600 applying an insulation structure (e.g., the insulation structure 102 of FIG. 1, the insulation structure 202 of FIG. 2, the insulation structure 302 of FIG. 3, the insulation structure 418 of FIG. 4, the insulation structure 600 of FIG. 6) to the first conductive surface of the conductive layer. The insulation structure includes an adhesive layer (e.g., the adhesive layer 118 of FIG. 1, the adhesive layer 316 of FIG. 3, the adhesive layer 604 of FIG. 6) and an insulation layer (e.g., the insulation layer 116 of FIG. 1, the insulation layer 314 of FIG. 3, the insulation layer 602) separated from the conductive layer by the adhesive layer in a first direction.

At block 1606, the method 1600 patterning the conductive layer to form a first lead (e.g., the first lead 104 of FIG. 1, the first lead 210 of FIG. 2, the first lead 306 of FIG. 3, the first lead 1000 of FIG. 10) and a second lead (e.g., the second lead 106 of FIG. 1, the second lead 212 of FIG. 2, the second lead 308 of FIG. 3, the second lead 1002), separated by a gap exposing the adhesive layer. The insulation structure extends continuously from the first lead to the second lead.

At block 1608, the method 1600 affixing a die (e.g., the die 120 of FIG. 1, the die 318 of FIG. 3, the die 422 of FIG. 4, the die 1100 of FIG. 11) to the adhesive layer in the gap.

At block 1610, the method 1600 attaching bond wires (e.g., the first bond wire 122 and the second bond wire 124 of FIG. 1, the first bond wire 1102 and the second bond wire 1104 of FIG. 12) between the die and the first and second lead.

At block 1612, the method 1600 encapsulating the bond wires, the first lead, the second lead, the die, and the insulation structure in a first mold section (e.g., the first mold section 128 of FIG. 1, the first mold section 228 of FIG. 2, the first mold section 322 of FIG. 3, the first mold section 414 of FIG. 4, the first mold section 1200 of FIG. 12) of a mold compound (e.g., the mold compound 126 of FIG. 1, the mold compound 226 of FIG. 2). Accordingly, the insulation structure of the semiconductor device provides support for the die thereby reducing material usage while simplifying the manufacturing process.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/-10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A semiconductor device comprising:
a conductive layer including a first lead and a second lead separated by a gap, the conductive layer extending from a first conductive surface to a second conductive surface in a first direction and from a first lead outer edge of the first lead to a second lead outer edge of the second lead in a second direction;
an insulation structure applied to the first conductive surface of the conductive layer and extending continuously from the first lead outer edge to the second lead outer edge, wherein the insulation structure includes an adhesive layer and an insulation layer separated from the conductive layer by the adhesive layer;
a die affixed to the adhesive layer in the gap; and
bond wires between the die and the first lead and the second lead.

2. The semiconductor device of claim 1, further comprising:
a substrate having at least a first terminal and a second terminal; and
a solder layer having a first solder portion over the first terminal and a second solder portion over the second terminal, wherein the first lead is affixed to the first terminal at the first solder portion and the second lead is affixed to the second terminal at the second solder portion.

3. The semiconductor device of claim 2, further comprising:
mold compound including a first mold section encapsulating the bond wires, the first lead, the second lead, the die, and the insulation structure, and a second mold section formed on the insulation layer of the insulation structure, and wherein the solder layer has a solder height in the first direction such that the first mold section is spaced apart from the substrate.

4. The semiconductor device of claim 3, wherein the first lead outer edge extends approximately to a sidewall of the second mold section.

5. The semiconductor device of claim 3, wherein the substrate has an upper surface, a base surface, and a recess extending from the upper surface toward the base surface, and wherein the first mold section extends into the recess.

6. The semiconductor device of claim 3, wherein the first lead includes a first lead portion and a second lead portion extending in the second direction, the first lead portion and the second lead portion separated by a third lead portion extending in approximately the first direction.

7. The semiconductor device of claim 3, wherein the first mold section has a first mold section dimension extending from the conductive layer to a mold section outer surface and the solder height is greater than the first mold section dimension.

8. The semiconductor device of claim 1, wherein the conductive layer is a copper foil with thickness of approximately 150 microns.

9. The semiconductor device of claim 1, wherein the insulation structure is a polyimide tape.

10. An integrated circuit (IC) device comprising:
a conductive layer including a first lead and a second lead separated by a gap, the conductive layer extending from a first conductive surface to a second conductive surface in a first direction and from a first lead outer edge of the first lead to a second lead outer edge of the second lead in a second direction;
an insulation structure applied to the first conductive surface of the conductive layer and extending continuously from the first lead outer edge to the second lead outer edge, wherein the insulation structure includes an adhesive layer and an insulation layer separated from the conductive layer by the adhesive layer;
a die affixed to the adhesive layer in the gap;
bond wires between the die and the first lead and the second lead;
a mold compound including a first mold section encapsulating the bond wires, the first lead, the second lead, the die, and the insulation structure, and a second mold section formed on the insulation layer of the insulation structure;
a substrate having a first terminal and a second terminal; and
a solder layer having a first solder portion over the first terminal and a second solder portion over the second terminal, wherein the first lead is affixed to the first terminal at the first solder portion and the second lead is affixed to the second terminal at the second solder portion.

11. The IC device of claim 10, wherein the first lead outer edge extends approximately to a sidewall of the second mold section.

12. The IC device of claim 10, wherein the substrate has an upper surface, a base surface, and a recess extending from the upper surface toward the base surface, and wherein the mold compound includes the second mold section formed on the insulation layer of the insulation structure and the first mold section extends into the recess.

13. The IC device of claim 10, wherein the first lead includes a first lead portion and a second lead portion extending in the second direction, the first lead portion and the second lead portion separated by a third lead portion extending in approximately the first direction.

14. The IC device of claim 10, wherein the solder layer has a solder height in the first direction such that the first mold section is spaced apart from the substrate, and wherein the first mold section has a first mold section dimension extending from the conductive layer to a mold section outer surface and the solder height is greater than the first mold section dimension.

15. The IC device of claim 10, wherein the insulation layer is a polyimide tape.

16. A method for forming an integrated circuit (IC) device, the method comprising:
providing a conductive layer having a first conductive surface and a second conductive surface;
applying an insulation structure to the first conductive surface of the conductive layer, wherein the insulation structure includes an adhesive layer and an insulation layer separated from the conductive layer by the adhesive layer in a first direction;
patterning the conductive layer to form a first lead and a second lead separated by a gap exposing the adhesive layer;
affixing a die to the adhesive layer in the gap;
attaching bond wires between the die and the first lead and the second lead; and
encapsulating the bond wires, the first lead, the second lead, the die, and the insulation structure in a first mold section of a mold compound.

17. The method of claim 16, further comprising:
affixing a first lead to a first terminal of a substrate and a second lead to a second terminal of the substrate.

18. The method of claim 17, wherein the first lead is affixed to the first terminal with a first solder portion of a solder layer and the second lead is affixed to the second terminal with a second solder portion of the solder layer, and wherein the solder layer has a solder height in the first direction such that the first mold section is spaced apart from the substrate.

19. The method of claim 17, wherein the substrate has an upper surface, a base surface, and a recess extending from the upper surface toward the base surface, and wherein the mold compound includes a second mold section formed on the insulation layer of the insulation structure and the first mold section extends into the recess.

20. The method of claim 16, further comprising:
applying a second mold section on the insulation layer of the insulation structure, the second mold section having a first sidewall opposite a second sidewall in a second direction; and
trimming the conductive layer and the insulation structure to form a first lead outer edge parallel to the first sidewall and a second lead outer edge parallel to the second sidewall.
